(19) United States
(12) Patent Application Publication
(10) Pub. No.: US 2025/0191651 A1
(43) Pub. Date: Jun. 12, 2025

(54) PULSE SIGNAL GENERATOR TO REDUCE POWER CONSUMPTION OF SRAM AND SRAM HAVING THE SAME

(71) Applicant: UIF (University Industry Foundation), Yonsei University, Seoul (KR)

(72) Inventors: Seong Ook JUNG, Seoul (KR); Seung Jae YEI, Seoul (KR); Keon Hee CHO, Seoul (KR); Min June YEO, Seoul (KR)

(21) Appl. No.: 18/882,268

(22) Filed: Sep. 11, 2024

(30) Foreign Application Priority Data
Dec. 12, 2023 (KR) 10-2023-012808

(51) Int. Cl. G11C 11/419; G11C 11/412; H03K 5/00; H03K 5/134; H03K 19/20

(52) U.S. Cl. CPC G11C 11/419; G11C 11/412; H03K 5/134; H03K 2005/00019; H03K 19/20

(57) ABSTRACT

The present disclosure provides a pulse signal generator capable of reducing power consumption by varying the width of a word line signal depending on temperature, including a delay unit which receives a clock signal, delays the signal, and outputs a delayed clock signal while adjusting the delay time of the delayed clock signal depending on temperature, and a pulse generation circuit which receives a clock signal and a delayed clock signal, whose delay time is adjusted depending on temperature, and logically combines them to generate a pulse signal having a pulse width that varies depending on temperature, and an SRAM having the same.

### CROSS-REFERENCE TO RELATED APPLICATIONS

This application claims priority under 35 U.S.C. § 119(a) to Korean Patent Application No. 10-2023-0120808, filed on Sep. 12, 2023, with the Korean Intellectual Property Office, the disclosure of which is incorporated herein in its entirety by reference.

### BACKGROUND

### 1. Technical Field

The present disclosure relates to a pulse generator and an SRAM having the same, and more particularly to a pulse signal generator capable of reducing power consumption of an SRAM by controlling a pulse width depending on temperature, and an SRAM having the same.

### 2. Description of the Related Art

SRAM (Static Random Access Memory), a type of semiconductor memory device, is widely used in various fields due to its characteristic of having a much faster operating speed than DRAM (Dynamic Random Access Memory).

FIG. 1 shows an example of a bit cell structure of an SRAM, and FIGS. 2A and 2B show the pulse width of a word line signal required depending on temperature.

FIG. 1 illustrates the structure of a 6T (transistor) bit cell (BC) having six transistors (PU1, PU2, PD1, PD2, PG1, PG2), which is the most representative cell structure in SRAM. As shown in FIG. 1, the bit cell (BC) includes pull-up transistors (PU1, PU2), pull-down transistors (PD1, PD2), and gate transistors (PG1, PG2), which are each connected in series between the power supply voltage (V_{DD}) and the ground voltage (V_{SS}). The gate transistors (PG1, PG2) are connected between the node between the pull-up transistors (PU1, PU2) and the pull-down transistors (PD1, PD2) and the bit line pair (BL/BLB), and the gate is connected to the word line (WL). The gates of the first pull-up transistor (PU1) and the first pull-down transistor (PD1) are commonly connected to one end of the second gate transistor (PG2), and the gates of the second pull-up transistor (PU2) and the second pull-down transistor (PD2) are commonly connected to one end of the first gate transistor (PG1). Therefore, the pull-up transistors (PU1, PU2) and the pull-down transistors (PD1, PD2) can be viewed as two inverters with cross-connected inputs and outputs, forming a latch that stores 1 bit of data.

Meanwhile, during a read operation, SRAM first precharges the bit line pair (BL/BLB) with a precharge voltage (e.g., power supply voltage (V_{DD})), and then, when the word line signal to the word line (WL) connected to the bit cell (BC) rises to the first voltage (e.g., power supply voltage (V_{DD})) level, two gate transistors (PG1, PG2) are turned on to electrically connect the bit line pair (BL/BLB) and the latch composed of two inverters. When the bit line pair (BL/BLB) and the latch are electrically connected, a current path is formed from one of a pair of bit lines (BL/BLB) (here, the bit line (BL) as an example) to the ground voltage (V_{SS}) through the turned-on pull-down transistor among the two pull-down transistors (PD1, PD2) depending on the bit value stored in the latch, and the read current (I_{read}) flows, thereby generating a voltage difference in the bit line pair (BL/BLB). Then, a sense amplifier (not shown) detects and amplifies the voltage difference generated in a bit line pair (BL/BLB) to determine the data stored in the bit cell (BC).

At this time, the amount of read current (I_{read}) varies depending on the temperature. As shown in FIG. 2A, at a high temperature (Hot Temperature: HT), a large read current (I_{read}@HT) flows, so that a voltage difference that can be detected by a sense amplifier in the bit line pair (BL/BLB) appears quickly. On the other hand, as shown in FIG. 2B, at a low temperature (Cold Temperature: CT), a small read current (I_{read}@CT) flows, so that the voltage difference appears slowly. In other words, at a high temperature, data can be determined quickly, while at a low temperature, data is determined relatively slowly.

Afterwards, when the word line signal transitions downwards to a second voltage (e.g., ground voltage (V_{SS})) level, the connection between the bit line pair (BL/BLB) and the latch is disconnected, and the bit line pair (BL/BLB) can be precharged again to the precharge voltage for the next read operation. That is, the word line signal may be applied to the word line in a pulse form.

Since SRAM must be able to operate stably not only at high temperatures but also at low temperatures, the word line signal in SRAM has a fixed long pulse width based on the pulse width required at low temperatures, as shown in FIG. 2B. However, when using SRAM with word line signals of such long pulse width at high temperatures, a large read current (I_{read}@HT) flows for a long time, causing the voltage of the bit line (BL) to drop significantly, as shown in FIG. 2A. In other words, a large amount of discharge occurs in the bit line (BL). Therefore, there is a problem that power consumption increases when precharging the bit line pair (BL/BLB) for the next read operation.

### SUMMARY OF THE INVENTION

An object of the present disclosure is to provide a pulse signal generator capable of reducing power consumption by varying the width of a word line signal depending on temperature, and an SRAM having the same.

According to one embodiment of the present disclosure, the pulse signal generator comprises: a delay unit that receives a clock signal, delays the clock signal, and outputs a delay clock signal while adjusting a delay time of the delay clock signal depending on temperature; and a pulse generation circuit that receives the clock signal and the delay clock signal whose delay time is adjusted depending on temperature, and logically combines them to generate a pulse signal having a pulse width that varies depending on temperature.

The delay unit may include: an upper voltage generator that adjusts an upper voltage, which is a voltage of an upper node, depending on a voltage level of the clock signal and temperature; a lower voltage generator that adjusts a lower voltage, which is a voltage of a lower node, depending on a voltage level of the clock signal and temperature; and a variable delay unit that outputs the delay clock signal by delaying the received clock signal by different times, with an output driving ability adjusted for a level change of the clock signal depending on the upper voltage and the lower voltage.

The variable delay unit may include a plurality of first variable inverters and a plurality of second variable inverters that are alternately connected in series to sequentially delay and transmit the received clock signal.

The first variable inverter may include a first PMOS transistor and first and second NMOS transistors connected in series between a power supply voltage and a ground voltage, and the clock signal or the output of the previously arranged second variable inverter may be applied to the gates of the first PMOS transistor and the first NMOS transistor depending on the arrangement position of the first variable inverter, and the lower voltage may be applied to the gate of the second NMOS transistor.

The second variable inverter may include second and third PMOS transistors and a third NMOS transistor, which are connected in series between a power supply voltage and a ground voltage, and the output of the first variable inverter previously arranged may be applied to the gates of the third PMOS transistor and the third NMOS transistor, and the upper voltage may be applied to the gate of the second PMOS transistor.

The upper voltage generator may lower the upper voltage to different voltage levels depending on the temperature when the applied clock signal has a rising transition.

The lower voltage generator may increase the lower voltage to different voltage levels depending on the temperature when the applied clock signal has a rising transition.

The upper voltage generator may include: a first upper circuit that, in response to a rising transition of the clock signal, lowers the voltage of the upper node, but lowers it to a different voltage level depending on the temperature; a second upper circuit that, in response to a rising transition of the clock signal, lowers the output voltage level, but lowers it to a different voltage level depending on the temperature; an upper buffer that buffers the applied clock signal and inputs it to the second upper circuit; and an upper capacitor that is connected between the upper node and an output of the second upper circuit and transmits a change in the output voltage level of the second upper circuit to the upper node by coupling.

The first upper circuit may include: a first upper PMOS transistor connected between a power supply voltage and the upper node, and having a gate to which the clock signal is applied; a first upper diode transistor implemented as an NMOS transistor having one end and a gate connected to the upper node; and a first upper NMOS transistor connected between the other end of the first upper diode transistor and a ground voltage, and having a gate to which the clock signal is applied.

The second upper circuit may include: a second upper PMOS transistor connected between a power supply voltage and the other end of the capacitor and having a gate to which the clock signal buffered in the upper buffer is applied; a second upper diode transistor implemented as an NMOS transistor having one end and a gate connected to the other end of the capacitor; and a second upper NMOS transistor connected between the other end of the second upper diode transistor and a ground voltage, and having a gate to which the clock signal buffered in the upper buffer is applied.

The lower voltage generator may include: a lower inverter that receives the clock signal, inverts it, and outputs an inverted clock signal; a first lower circuit that increases the voltage of the lower node in response to a falling transition of the inverted clock signal, but increases it to a different voltage level depending on the temperature; a second lower circuit that increases the output voltage level in response to a falling transition of the inverted clock signal, but increases it to a different voltage level depending on the temperature; a lower buffer that buffers the inverted clock signal and inputs it to the second lower circuit; and a lower capacitor that is connected between the lower node and the output of the second lower circuit, and transmits a change in the output voltage level of the second lower circuit to the lower node by coupling.

The first lower circuit may include: a first lower PMOS transistor having one end connected to a power supply voltage and having a gate to which the inverted clock signal is applied; a first lower diode transistor implemented as an NMOS transistor having one end and a gate connected to the other end of the first lower PMOS transistor and the other end connected to the lower node; and a first lower NMOS transistor connected between the lower node and a ground voltage and having a gate to which the inverted clock signal is applied.

The second lower circuit may include: a second lower PMOS transistor having one end connected to a power supply voltage and having a gate to which the inverted clock signal buffered in the lower buffer is applied; a second lower diode transistor implemented as an NMOS transistor having one end and a gate connected to the other end of the first lower PMOS transistor and the other end connected to the other end of the capacitor; and a second lower NMOS transistor connected between the other end of the capacitor and a ground voltage and having a gate to which the inverted clock signal buffered in the lower buffer is applied.

The pulse generation circuit may include: an inverter that inverts the delay clock signal and outputs an inverted delay clock signal; and a logical AND circuit that logically ANDs the clock signal and the inverted delay clock signal to output the logical AND.

According to another embodiment of the present disclosure, the SRAM comprises: a cell array in which a plurality of bit cells is arranged, defined by a plurality of word lines and a plurality of bit line pairs; and a word line driver having at least one pulse signal generator for outputting a word line signal having a pulse width that varies depending on temperature to the plurality of word lines.

The pulse signal generator of the present disclosure and the SRAM having the same can reduce power consumption for precharge during a read operation, by controlling the width of a pulse-form word line signal depending on temperature.

### BRIEF DESCRIPTION OF THE DRAWINGS

FIG. 1 shows an example of a bit cell structure of an SRAM.

FIGS. 2A and 2B show a pulse width of a word line signal required depending on temperature.

FIG. 3 shows a schematic structure of an SRAM.

FIG. 4 shows a structure of a pulse signal generator.

FIG. 5 is a diagram for explaining a pulse width margin depending on temperature.

FIG. 6 shows a schematic structure of a delay unit according to the present disclosure.

FIG. 7 shows an example of a detailed structure of the delay unit of FIG. 6.

FIGS. 8 to 11 show pulse widths of word line signals and upper and lower voltages depending on clock signals.

FIGS. 12 to 15 show pulse widths of word line signals and upper and lower voltage changes depending on temperature.

FIG. 16 is a graph comparing pulse width changes and margins depending on temperature.

FIG. 17 is a graph comparing margins depending on temperature by process corner model.

FIG. 18 is a graph comparing power consumption of a delay unit and bit line precharge depending on temperature.

### DETAILED DESCRIPTION OF THE INVENTION

Hereinafter, the embodiments of the present disclosure will be described with reference to the accompanying drawings. The following detailed description is provided to assist full understanding of a method, apparatus and/or system disclosed in the present disclosure. However, this is only exemplary, and the present disclosure is not limited to the following description.

In describing exemplary embodiments of the present disclosure, when a detailed description of known art related to the present disclosure is determined to unnecessarily obscure the subject matter of the present disclosure, the detailed description will be omitted. The terms to be described below are terms defined in consideration of functions in the present disclosure and may vary according to an intention of a user or an operator or practice. Therefore, definitions thereof will be determined based on content of the entire specification. The terms used in the detailed description are merely intended to describe the exemplary embodiments of the present disclosure and should not be limited in any way. The singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof. Additionally, terms such as “. . . unit”, “. . . device”, “module”, and “block” described in the specification indicate a unit for processing at least one function or operation, which may be implemented by hardware, software or a combination of hardware and software.

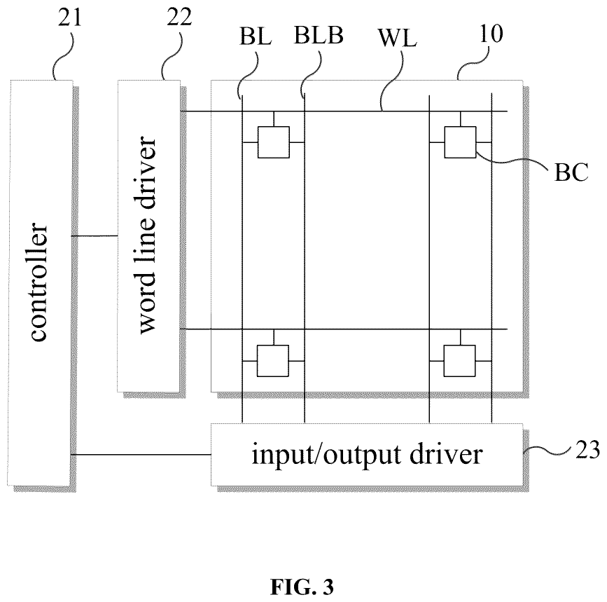

FIG. 3 shows a schematic structure of an SRAM.

Referring to FIG. 3, the SRAM may include a cell array 10, a controller 21, a word line driver 22, and an input/output driver 23.

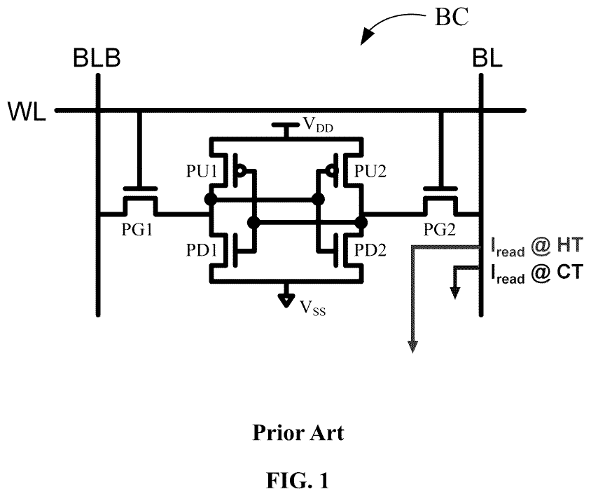

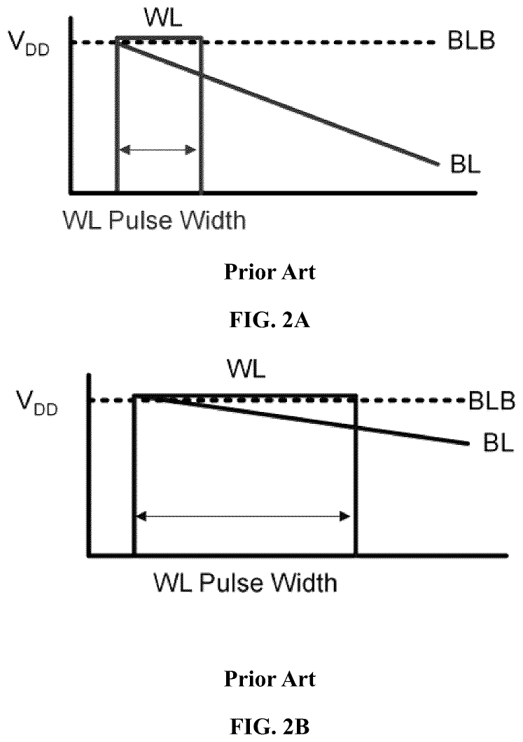

The cell array 10 includes a plurality of bit cells (BC). Here, in the cell array 10 as shown in FIG. 1, a plurality of word lines WL and a plurality of bit line pairs BL/BLB are formed in a direction in which they intersect each other, and the bit cells BC are arranged at positions where word lines WL and bit line pairs BL/BLB intersect, so that each of the plurality of bit cells BC may be connected to at least one of the plurality of word lines WL and at least one of the bit line pairs BL/BLB.

Each of the plurality of bit cells BC may be implemented as a 6T cell as shown in FIG. 1, but may also be implemented as other known SRAM bit cells such as 8T or 10T.

The controller 21 may receive a command, an address, and a clock and output a row address RA, a column address CA, and a control signal. The controller 21 may obtain a row address RA and a column address CA from the received address. The controller 21 may apply the obtained row address RA to the word line driver 22 and apply the column address CA to the input/output driver 23. In addition, the controller 21 may decode the command to generate a read control signal or a write control signal, etc.

In the present disclosure, the controller 21 includes at least one pulse signal generator, and the pulse signal generator generates a word line signal, which is a pulse signal, and transmits it to the word line driver 22, so that the word line signal generated can be applied to a word line WL selected according to a row address RA. At this time, the pulse signal generator may generate the word line signal using a clock signal, but may also generate the word line signal using a word line enable signal or another signal as one of the read control signals generated by the controller 21.

The word line driver 22 selects at least one of a plurality of word lines WL according to a read control signal and a row address RA received from the controller 21, and applies a word line signal in the form of a pulse to the selected word line WL, thereby allowing a plurality of bit cells BC arranged in the cell array 10 to be selected in units of rows.

The input/output driver 23 may be equipped with a plurality of sense amplifiers (not shown), and may detect data stored in a bit cell BC by detecting and amplifying the voltage difference between a plurality of bit line pairs BL/BLB according to a read control signal applied from the controller 21 during a read operation of the SRAM.

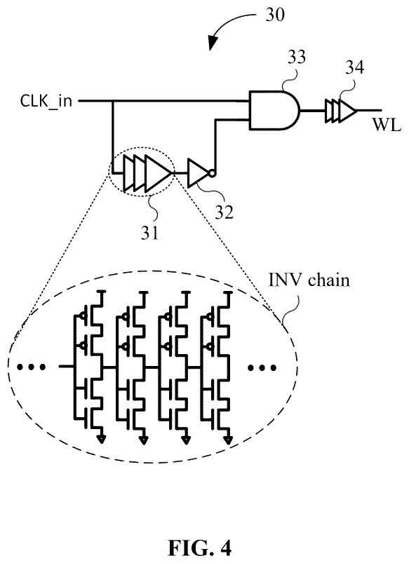

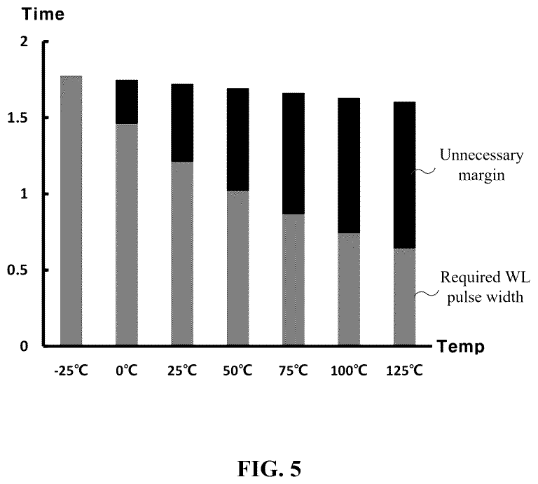

FIG. 4 shows a structure of a pulse signal generator, and FIG. 5 is a diagram for explaining a pulse width margin depending on temperature.

In FIG. 4, it is assumed that the pulse signal generator 30 provided in the controller 21 to generate a word line signal generates a word line signal, which is a pulse signal, by receiving a clock signal (CLK_in), but as described above, it may also generate a word line signal by receiving another signal. Then, the pulse signal generator 30 applies the generated word line signal to the word line WL.

The pulse signal generator 30 may include a delay unit 31, an inverter 32, and a pulse generation circuit 33. The delay unit 31 delays the clock signal CLK_in applied to the pulse signal generator 30 and outputs a delay clock signal CLK_delay, and the inverter 32 receives the delay clock signal CLK_delay, inverts it, and outputs it.

The pulse generation circuit 33 generates a pulse signal by performing a logical combination based on the clock signal CLK_in and the inverted delay clock signal CLK_delay. Here, the pulse generation circuit 33 may be implemented as an AND circuit as an example, as shown in FIG. 4. Accordingly, the pulse generation circuit 33 outputs the level of the word line signal as a high level only when both the clock signal CLK_in and the inverted delay clock signal CLK_delay have a high level, and outputs the level of the word line signal as a low level when at least one of the clock signal CLK_in and the inverted delay clock signal CLK_delay has a low level. Therefore, the pulse signal generator 30 can output the word line signal in the form of a pulse signal having a width equal to the time for which the delay unit 31 delays the clock signal CLK_in.

Here, for convenience of understanding, the inverter 32 is depicted separately from the pulse generation circuit 33, but the inverter 32 can also be seen as being included in the pulse generation circuit 33.

In addition, the pulse signal generator 30 may further include an output buffer circuit 34 composed of a plurality of buffers so that the word line WL driving capability of the word line driver 22 receiving the word line enable signal from the controller 21, i.e., the rising and falling transitions of the generated word line signal, are stably performed.

In general, in a pulse signal generator 30, the delay unit 31 is implemented as an inverter chain INV chain in which a plurality of inverters are connected in series, as shown in the enlarged lower drawing of FIG. 4, and delays the applied clock signal CLK_in for a certain period of time and outputs it. At this time, the pulse width of the word line signal is determined according to the time for which the delay unit 31 delays the clock signal CLK_in.

As described above, during the read operation of SRAM, a small read current (I_{read}@CT) flows at low temperatures, so that the voltage difference between the bit line pairs BL/BLB appears slowly, but at high temperatures, a large read current (I_{read}@HT) flows, so that the voltage difference between the bit line pairs BL/BLB appears quickly. Therefore, during the read operation of SRAM, the pulse width required for the actual word line signal according to temperature gradually decreases as shown in the lower gray portion of the bar graph of FIG. 5. However, SRAM must perform normal operation not only at high temperatures but also at low temperatures. Therefore, as shown in the lower part of FIG. 4, when the delay unit 31 in the pulse signal generator 30 is configured as an inverter chain INV chain to delay for a fixed period of time, the delay unit 31 must delay the clock signal CLK_in so that the SRAM can operate even at the lowest temperature that can be set (for example, −25° C. in FIG. 5). Accordingly, the delay unit 31 is configured to delay the clock signal CLK_in based on the SRAM operation at the lowest temperature. As a result, when the operating temperature of the SRAM is higher than the lowest temperature, an unnecessary margin is included in the pulse width, as shown in the upper black portion of the bar graph of FIG. 5. And the unnecessary margin increases further as the operating temperature of the SRAM increases, causing a larger voltage drop in the bit line pair BL/BLB. In other words, it becomes a factor that increases the power consumption of the SRAM.

However, if the delay unit 31 can adjust the time for delaying the clock signal CLK_in depending on the temperature, the pulse width of the word line signal can be varied depending on the temperature, which can reduce unnecessary margins and reduce the power consumption of the SRAM. Hereinafter, a delay unit that can vary the delay time depending on the temperature is described.

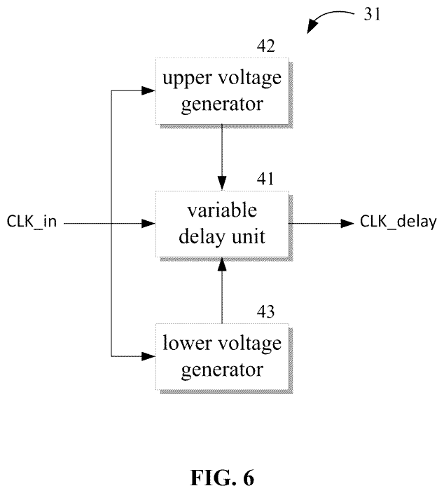

FIG. 6 shows a schematic structure of a delay unit according to the present disclosure.

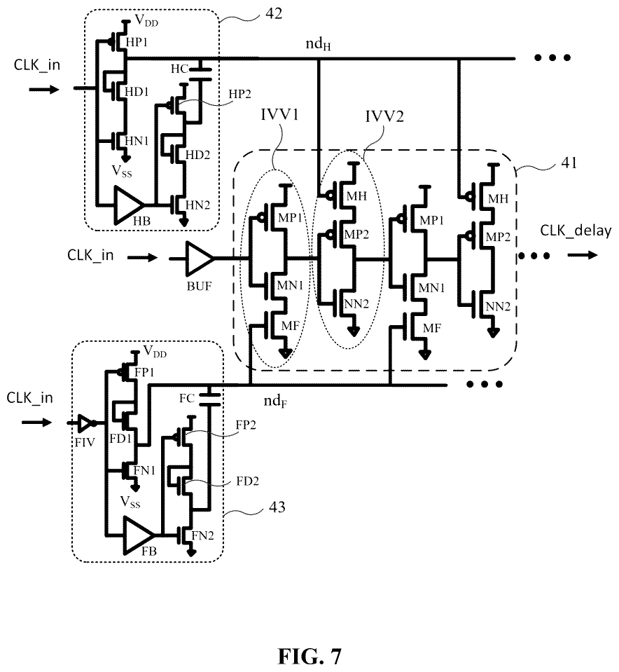

Referring to FIGS. 6 and 7, the delay unit of the present disclosure may include a variable delay unit 41, an upper voltage generator 42, and a lower voltage generator 43.

The upper voltage generator 42 and the lower voltage generator 43 each are activated by receiving a clock signal CLK_in, and output voltage levels of the upper voltage V_{GH} and the lower voltage V_{GF} by varying them depending on the temperature. The upper voltage generator 42 outputs the voltage level of the upper voltage V_{GH} by increasing it at low temperatures and decreasing it at high temperatures. On the other hand, the lower voltage generator 43 outputs the voltage level of the lower voltage V_{GF} by decreasing it at low temperatures and increasing it at high temperatures.

The variable delay unit 41 receives a clock signal CLK_in and outputs it by delaying it, but outputs it by varying the delay time in response to the upper voltage V_{GH} applied from the upper voltage generator 42 and the lower voltage V_{GF} applied from the lower voltage generator 43. At this time, the variable delay unit 41 may output it by reducing the delay time as the temperature rises in response to the upper voltage V_{GH} and the lower voltage V_{GF} whose voltage levels change depending on the temperature, while increasing the delay time as the temperature decreases.

Therefore, in the present disclosure, by implementing the delay unit 31 in the pulse signal generator 30 shown in FIG. 4 as the delay unit 40 of the present disclosure shown in FIG. 6, the pulse width of the word line signal can be adjusted depending on the temperature, thereby reducing unnecessary margins in the word line signal. This means that the voltage level of the bit line pair BL/BLB can be suppressed from dropping more than necessary during a read operation of the SRAM, which would otherwise increase power consumption when precharging with the precharge voltage thereafter. In other words, the power consumption of the SRAM can be reduced.

The upper voltage generator 42 and the lower voltage generator 43 can be integrated into an upper and lower voltage generator.

FIG. 7 shows an example of a detailed structure of the delay unit of FIG. 6.

Referring to FIG. 7, first, the variable delay unit 41 is configured to include first and second variable inverters IVV1 and IVV2 that are alternately connected in series with each other. The first variable inverter IVV1 includes a PMOS transistor MP1 and two NMOS transistors MN1 and MF that are connected in series between a power supply voltage VDD and a ground voltage Vss. The PMOS transistor MP1 and one NMOS transistor MN1 that are connected in series have their gates commonly connected to the input node of the first variable inverter IVV1, similar to a conventional inverter, and the node between the PMOS transistor MP1 and the NMOS transistor MN1 is an output node. In the first variable inverter IVV1, the remaining one NMOS transistor MF is a lower transistor, has a gate receiving the lower voltage V_{GF} applied through the lower node nd_{F} from the lower voltage generator 43, and adjusts the lowest voltage level of the signal output from the output node of the first variable inverter IVV1 according to the voltage level of the applied lower voltage V_{GF}.

The first variable inverter IVV1 basically has an inverter configuration, so when a signal applied to an input node transitions upward from a low level to a high level, it outputs a signal transitioning downward from a high level to a low level to an output node. At this time, in the case of a general inverter, the voltage of the signal output to the output node is pulled down to the ground voltage V_{SS} level and output, but the first variable inverter IVV1 may output the signal output to the output node by controlling the time for the voltage level of the signal to be pulled down to the ground voltage V_{SS} level according to the voltage level of the lower voltage V_{GF} rather than the input signal by the lower transistor MF.

In addition, since the lower voltage V_{GF} applied from the lower voltage generator 43 can vary depending on the temperature, the first variable inverter IVV1 can also output the output signal by adjusting the lowest voltage output delay time of the output signal depending on the temperature.

Meanwhile, the second variable inverter IVV2 includes two PMOS transistors MH and MP2 and one NMOS transistor MN2 connected in series between the power supply voltage VDD and the ground voltage V_{SS}. The gates of the one PMOS transistor MP2 and the NMOS transistor MN2 connected in series are commonly connected to the input node of the second variable inverter IVV2, and the node between the PMOS transistor MP2 and the NMOS transistor MN2 is the output node of the second variable inverter IVV2. In the second variable inverter IVV2, the PMOS transistor MH is an upper transistor, has a gate receiving the upper voltage V_{GH} applied through the upper node nd_{H} from the upper voltage generator 42, and adjusts the delay time for the signal output from the output node of the second variable inverter IVV2 to reach the maximum voltage level according to the voltage level of the applied upper voltage V_{GH}.

The second variable inverter IVV2 outputs a signal transitioning upward from a low level to a high level to an output node, when a signal applied to an input node transitions downward from a high level to a low level. At this time, in the second variable inverter IVV1, the upper transistor MH adjusts the delay time for the maximum voltage level of the signal output to the output node to reach the power supply voltage V_{DD} level according to the voltage level of the upper voltage V_{GH}. In addition, since the upper voltage V_{GH} applied from the upper voltage generator 42 can vary depending on the temperature, the second variable inverter IVV2 can output the output signal by adjusting the arrival delay time for the output signal to reach the maximum voltage level depending on the temperature.

In addition, the variable delay unit 41 may further include an input buffer BUF that buffers and transmits the applied clock signal CLK_in.

Meanwhile, the upper voltage generator 42 includes first and second upper adjustment circuits, an upper buffer HB, and an upper capacitor HC. The first upper adjustment circuit includes one PMOS transistor HP1 and two NMOS transistors HD1 and HN1 connected in series between the power supply voltage V_{DD} and the ground voltage V_{SS}. The region between the first upper PMOS transistor HP1 and the first upper diode transistor HD1 is the output node of the first upper adjustment circuit, and is connected to the upper node nd_{H}, which is the output node of the upper voltage generator 42. The gate of the first upper diode transistor HD1 is connected to its one end, that is, the other end of the first upper PMOS transistor HP1. Therefore, the first upper diode transistor HD1 can be viewed as having a diode connection structure.

A clock signal CLK_in is commonly applied to the gates of the first upper PMOS transistor HP1 and the first upper NMOS transistor HN1.

Meanwhile, the second upper adjustment circuit also includes one PMOS transistor HP2 and two NMOS transistors HD2 and HN2 connected in series between the power supply voltage V_{DD} and the ground voltage V_{SS}. Here, too, the region between the second upper PMOS transistor HP2 and the second upper diode transistor HD2 is the output node of the second upper adjustment circuit. However, the output node of the second upper adjustment circuit is not directly connected to the upper node nd_{H}, but is connected to the other end of the upper capacitor HC, one end of which is connected to the upper node nd_{H}.

In addition, the clock signal CLK_in is also commonly applied to the gates of the second upper PMOS transistor HP2 and the second upper NMOS transistor HN2. At this time, the clock signal (CLK_in) applied to the upper voltage generator 42 can be delayed and applied to the gates of the second upper PMOS transistor HP2 and the second upper NMOS transistor HN2 by the upper buffer HB.

The gate of the second upper diode transistor HD2 is also connected to its one end on the second upper PMOS transistor HP2 side, thereby having a diode connection structure.

The upper capacitor HC is connected between the upper node nd_{H} and the output node of the second upper adjustment circuit.

The lower voltage generator 43 also includes first and second lower adjustment circuits, a lower buffer FB and a lower capacitor FC similar to the upper voltage generator 42, but further includes a lower inverter FIV that inverts the applied clock signal CLK_in. The lower inverter FIV inverts the clock signal CLK_in and outputs it to the first and second lower adjustment circuits.

The first lower adjustment circuit includes one PMOS transistor FP1 and two NMOS transistors FD1 and FN1 connected in series between the power supply voltage V_{DD} and the ground voltage V_{SS}, similar to the first upper adjustment circuit. In addition, the gate of the first lower diode transistor FD1 is connected to its one end on the first lower PMOS transistor FP1 side, thereby having a diode connection structure.

In the first lower adjustment circuit, the region between the first lower diode transistor FD1 and the first lower NMOS transistor FN1 is the output node, and is connected to the lower node nd_{F}, which is the output node of the lower voltage generator 43.

In addition, an inverted clock signal CLK_inb inverted in the lower inverter FIV is commonly applied to the gates of the first lower PMOS transistor FP1 and the first lower NMOS transistor FN1.

Meanwhile, the second lower adjustment circuit also includes one PMOS transistor FP2 and two NMOS transistors FD2 and FN2 connected in series between the power supply voltage V_{DD} and the ground voltage V_{SS}. Here, too, as with the first lower adjustment circuit, the region between the second lower diode transistor FD2 and the second lower NMOS transistor FN2 is the output node of the second lower adjustment circuit. Similarly to the second upper adjustment circuit, the output node of the second lower adjustment circuit is also not directly connected to the lower node nd_{F}, but is connected to the other end of the lower capacitor FC, one end of which is connected to the lower node nd_{F}. In addition, the gate of the second lower diode transistor FD2 is connected to its one end on the second lower PMOS transistor FP2 side, thereby having a diode connection structure.

The inverted clock signal CLK_inb is also commonly applied to the gates of the second lower PMOS transistor FP2 and the second lower NMOS transistor FN2. At this time, the inverted clock signal CLK_inb output from the lower inverter FIV may be delayed and applied to the gates of the second lower PMOS transistor FP2 and the second lower NMOS transistor FN2 by being buffered by the lower buffer FB.

The lower capacitor FC is connected between the lower node nd_{F} and the output node of the second lower adjustment circuit.

That is, in the upper voltage generator 42 and the lower voltage generator 43, the first upper adjustment circuit and the first lower adjustment circuit are the same except for the location of the output node, and the second upper adjustment circuit and the second lower adjustment circuit are also the same except for the location of the output node, and can be viewed as having a structure in which an NMOS transistor having a diode connection configuration is added between the PMOS transistor and the NMOS transistor of the inverter. In addition, there is a difference in that the lower voltage generator 43 further include a lower inverter FIV compared to the upper voltage generator 42.

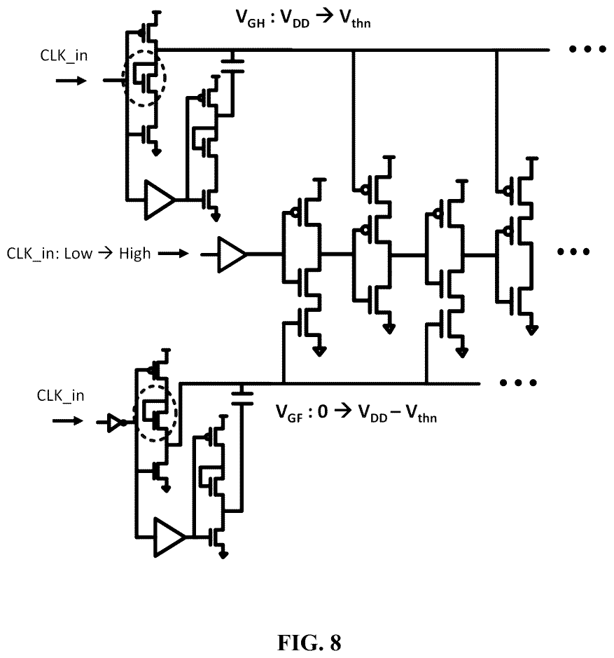

FIGS. 8 to 11 show pulse widths of word line signals and upper and lower voltages depending on clock signals.

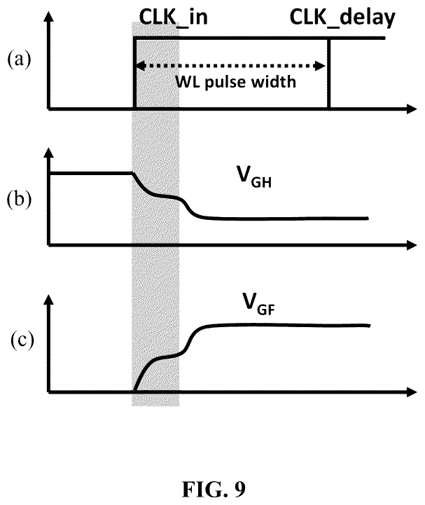

Referring to FIGS. 8 and 9, first, as in (a) of FIG. 9, when the clock signal CLK_in is applied by making a rising transition from a low level to a high level, in the upper voltage generator 42 the clock signal CLK_in that is making a rising transition is applied as is to the first upper adjustment circuit, and in the lower voltage generator 43 the clock signal CLK_in is inverted by the lower inverter FIV and the inverted clock signal (CLK_inb) that is made a falling transition is applied to the first lower control circuit.

As described above, since the first upper adjustment circuit and the first lower adjustment circuit basically have an inverter configuration, the first upper adjustment circuit outputs a signal that undergoes a falling transition to an output node in response to a rising transition of a clock signal CLK_in, and a first lower adjustment circuit outputs a signal that undergoes a rising transition to an output node in response to a falling transition of an inverted clock signal CLK_inb. However, the first upper diode transistor HD1 and the first lower diode transistor FD1 provided in each of the first upper adjustment circuit and the first lower adjustment circuit have a diode connection structure.

Accordingly, the first upper adjustment circuit cannot pull down the output signal from the power supply voltage V_{DD} level to the ground voltage V_{SS}, and outputs it at the threshold voltage Vₜₕₙ level of the first upper diode transistor HD1, as shown in (b) of FIG. 9. In addition, as shown in (d) of FIG. 9, the first lower adjustment circuit cannot pull up the output signal from the ground voltage V_{SS} to the power supply voltage V_{DD} level, and thus outputs it at a level V_{DD}−Vₜₕₙ that is the threshold voltage Vₜₕₙ (for convenience of explanation, it is assumed here that the threshold voltages of all diode transistors are the same) of the first lower diode transistor FD1 subtracted from the power supply voltage _{VDD}.

That is, the upper voltage V_{GH} of the upper node nd_{H} has the threshold voltage Vₜₕₙ level, and the lower voltage V_{GF} of the lower node nd_{F} has a voltage level V_{DD}−Vₜₕₙ that is the threshold voltage Vₜₕₙ subtracted from the power supply voltage V_{DD}.

At this time, the second upper adjustment circuit and the second lower adjustment circuit receive the clock signal CLK_in and the inverted clock signal CLK_inb buffered by the upper and lower buffers HB and FB, so the output signal does not change.

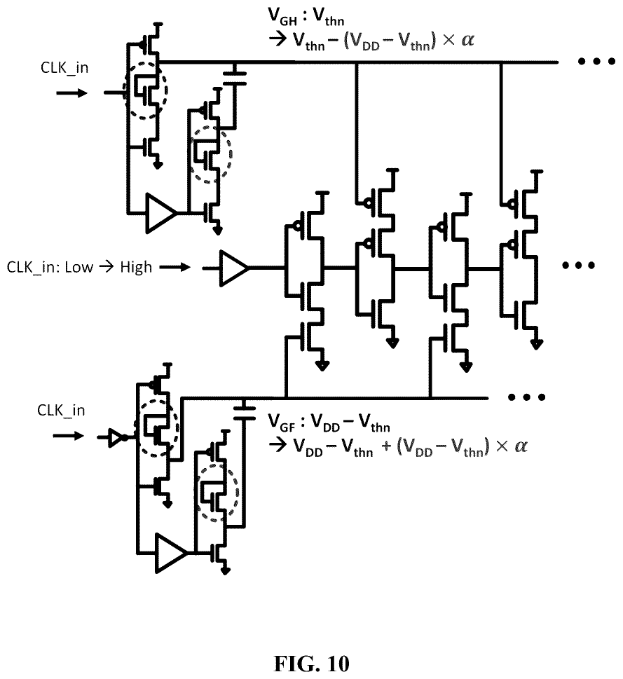

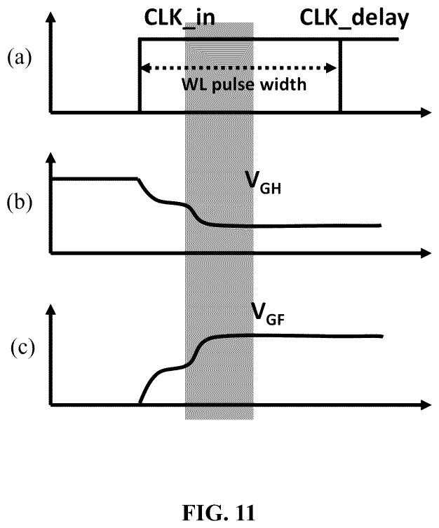

Meanwhile, referring to FIGS. 10 and 11, the clock signal CLK_in and the inverted clock signal CLK_inb buffered by the upper and lower buffers HB and FB are applied to the second upper adjustment circuit and the second lower adjustment circuit, respectively. Accordingly, the output of the second upper adjustment circuit is lowered from the power supply voltage V_{DD} level to the threshold voltage Vₜₕₙ of the second upper diode transistor HD2, similar to the first upper adjustment circuit. In addition, by the coupling of the upper capacitor HC, the output voltage change of the second upper adjustment circuit is reflected to the upper node nd_{H}, so that the upper voltage V_{GH} of the upper node nd_{H} has a voltage level Vₜₕₙ−(V_{DD}−Vₜₕₙ)×α that is the output voltage change V_{DD}−Vₜₕₙ of the second upper adjustment circuit weighted by the temperature coefficient a of the upper capacitor HC subtracted from the threshold voltage Vₜₕₙ, as shown in (b) of FIG. 11.

In addition, the output of the second lower adjustment circuit increases from the ground voltage V_{SS} to the voltage level V_{DD}−Vₜₕₙ according to the difference between the power supply voltage V_{DD} and the threshold voltage Vₜₕₙ. The output voltage change of the second lower adjustment circuit is reflected to the lower node nd_{F} by the coupling of the lower capacitor FC, so that the lower voltage V_{GF} of the lower node nd_{F} has a voltage level (V_{DD}−Vₜₕₙ)+(V_{DD}−Vₜₕₙ)×α that is the output voltage change V_{DD}−Vₜₕₙ of the second upper adjustment circuit at the voltage level V_{DD}−Vₜₕₙ plus the output voltage change V_{DD}−Vₜₕₙ of the second upper adjustment circuit weighted by the temperature coefficient α of the lower capacitor FC, as shown in (c) of FIG. 11.

That is, the upper voltage V_{GH} of the upper node nd_{H} has a level of Vₜₕₙ−(V_{DD}−Vₜₕₙ)×α, and the lower voltage V_{GF} of the lower node nd_{F} has a level of (V_{DD}−Vₜₕₙ)+(V_{DD}−Vₜₕₙ)×α.

Accordingly, the upper voltage V_{GH} is applied to the gate of the upper transistor MH of the first variable inverter IVV1 while changing from the threshold voltage Vₜₕₙ level to the Vₜₕₙ−(V_{DD}−Vₜₕₙ)×α level, and the lower voltage V_{GF} is applied to the gate of the lower transistor MF of the second variable inverter IVV2 while changing from the V_{DD}−Vₜₕₙ level to the (V_{DD}−Vₜₕₙ)+(V_{DD}−Vₜₕₙ)×α level.

In the variable delay unit 41, the clock signal CLK_in is delayed through the input buffer BUF and applied to the first variable inverter IVV1, and the first variable inverter IVV1 outputs a signal that undergoes a falling transition in response to the clock signal CLK_in undergoing a rising transition. At this time, since the gate of the lower transistor MF is connected to the lower node nd_{F}, the first variable inverter IVV1 adjusts the delay time until the output signal is pulled down by the lower voltage V_{GF} of (V_{DD}−Vₜₕₙ)+(V_{DD}−Vₜₕₙ)×α) output from the lower voltage generator 43 to the lower node nd_{F}. That is, the falling transition driving capability of the first variable inverter IVV1 is controlled.

In addition, since the gate of the upper transistor MH is connected to the upper node nd_{H}, the second variable inverter IVV2 adjusts the delay time until the output signal is pulled up by the upper voltage V_{GH} of Vₜₕₙ−(V_{DD}−Vₜₕₙ)×α) output from the upper voltage generator 42 to the upper node nd_{H}. Accordingly, the rising transition driving capability of the second variable inverter IVV2 is controlled.

In particular, in the variable delay unit 41, since a plurality of first variable inverters IVV1 and a plurality of second variable inverters IVV2 are alternately connected in series, the change in the driving ability of the first and second variable inverters IVV1 and IVV2 can change the timing at which the delay clock signal CLK_delay makes a rising transition after the clock signal CLK_in makes a rising transition.

By the pulse generation circuit 33 shown in FIG. 4, the word line signal in the form of a pulse is generated by making a rising transition when the clock signal CLK_in makes a rising transition and making a falling transition when the delayed clock signal CLK_delay makes a rising transition. Therefore, when the timing at which the delayed clock signal CLK_delay makes a rising transition changes, the pulse width of the word line signal changes.

In addition, the first variable inverter IVV1 is controlled for its falling transition driving capability for the rising transition of the input signal, while the second variable inverter IVV2 is controlled for its rising transition driving capability for the falling transition of the input signal. Therefore, when the clock signal CLK_in makes a falling transition from a high level to a low level, there is no significant change in the driving capability.

At this time, the pulse signal generator 30 inverts the delayed clock signal CLK_delay output from the delay unit 31 and performs a logical AND operation with the clock signal CLK_in to generate a word line signal in the form of a pulse, so that the falling transition of the clock signal CLK_in and the delayed clock signal CLK_delay does not affect the word line signal.

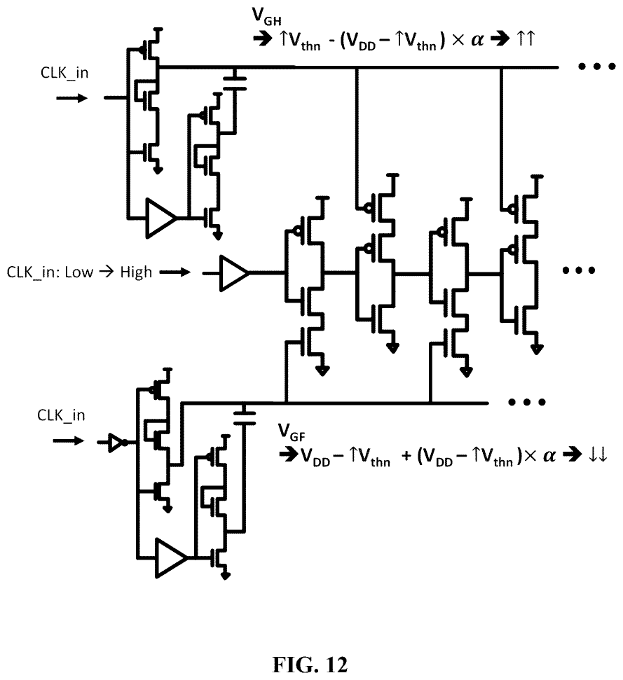

FIGS. 12 to 15 show pulse widths of word line signals and upper and lower voltage changes depending on temperature.

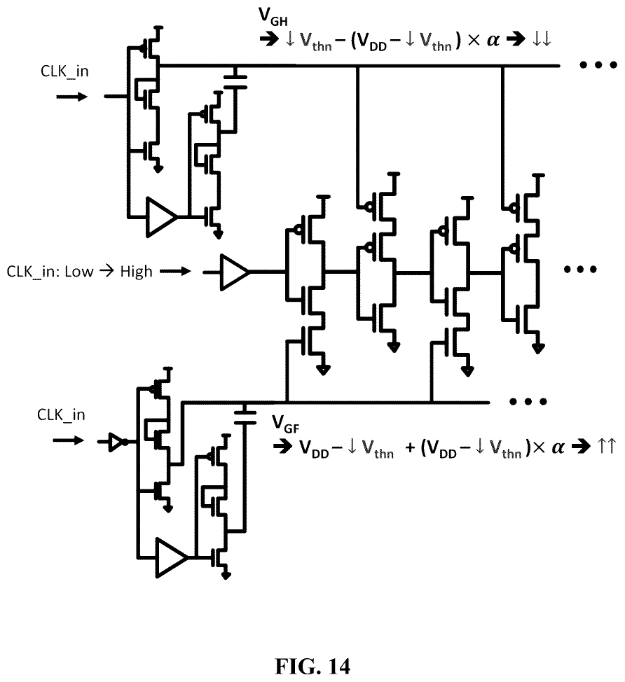

As described above, in the delay unit 40 of the present disclosure, the first and second upper adjustment circuits and the first and second lower adjustment circuits of the upper voltage generator 42 and the lower voltage generator 43 each have first and second upper diode transistors HD1 and HD2 and first and second lower diode transistors FD1 and FD2 having a diode connection structure. In addition, it is well known that the threshold voltage Vₜₕₙ of the diode-connected transistors (HD1 and HD2) and (FD1 and FD2) varies depending on the temperature. As shown in FIG. 12, the threshold voltage Vₜₕₙ of the diode-connected transistors (HD1 and HD2) and (FD1 and FD2) increases as the temperature decreases, while as shown in FIG. 14, it decreases as the temperature increases.

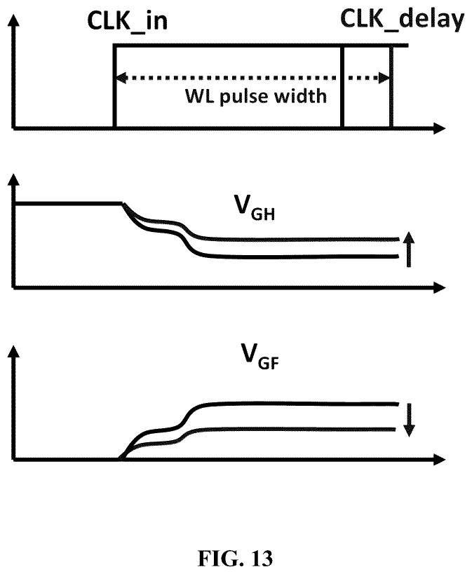

Therefore, when the operating temperature of the SRAM is low, the threshold voltage Vₜₕₙ of the diode transistors (HD1 and HD2) and (FD1 and FD2) increases, so that the voltage level of the upper voltage V_{GH} increases as shown in (b) of FIG. 13, and the voltage level of the lower voltage V_{GF} decreases as shown in (c) of FIG. 13. This further reduces the driving ability of the variable delay unit 41 at low temperatures, so that the time for the delay clock signal CLK_delay to make a rising transition is further delayed, thereby lengthening the pulse width of the word line signal as shown in (a) of FIG. 13.

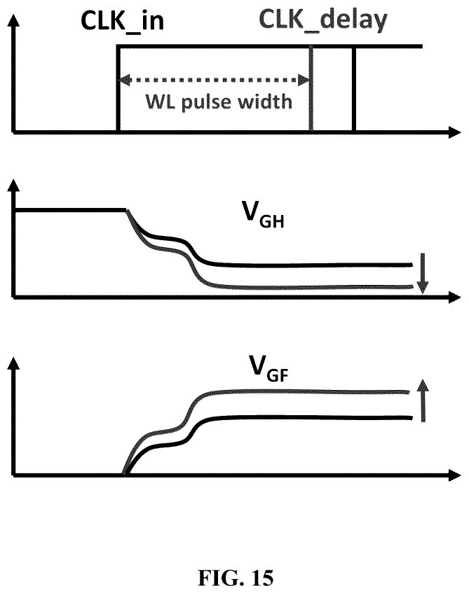

In contrast, when the operating temperature of the SRAM is high, the threshold voltage Vₜₕₙ of the diode transistors (HD1 and HD2) and (FD1 and FD2) is lowered, so that the voltage level of the upper voltage V_{GH} is lowered as shown in (b) of FIG. 15, and the voltage level of the lower voltage V_{GF} is increased as shown in (c) of FIG. 15. Therefore, the driving capability of the variable delay unit 41 at high temperatures is improved, so that the time for the delay clock signal CLK_delay to make a rising transition is shortened, thereby shortening the pulse width of the word line signal as shown in (a) of FIG. 15.

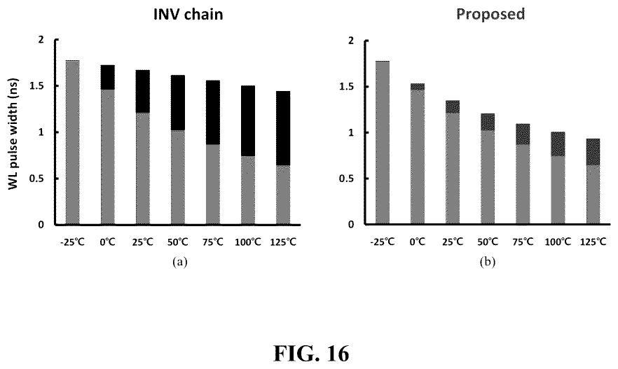

FIG. 16 is a graph comparing pulse width changes and margins depending on temperature.

In FIG. 16, (a) shows a case where the delay unit 31 is configured as a conventional inverter chain INV chain as in FIG. 4, and (b) shows a case where it is implemented as a delay unit 40 of the present disclosure as shown in FIG. 7. In FIG. 16, each bar graph represents a time according to the pulse width of the word line signal generated by the pulse signal generator 30, and the lower part of each bar graph represents the pulse width required for the actual word line signal according to the temperature, and the upper part represents the unnecessary margin. Comparing (a) and (b), it can be seen that the pulse signal generator 30 of the present disclosure does not significantly increase the unnecessary margin even when the temperature increases. Here, even when the delay unit 31 is implemented as an inverter chain INV chain, as shown in (a), the pulse width of the word line signal is reduced, albeit slightly, because even transistors that do not have a diode connection configuration are affected to some extent by temperature.

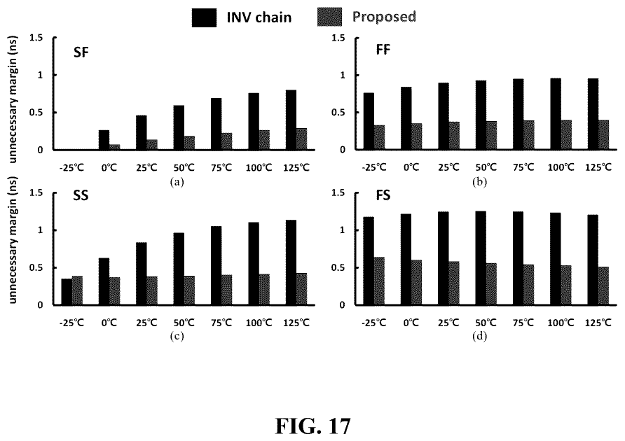

FIG. 17 is a graph comparing margins depending on temperature by process corner model.

In FIG. 17, (a) to (d) represent unnecessary margins according to the SF (slow/fast), FF (fast/fast), SS (slow/slow), and FS (fast/slow) corner processes based on the carrier mobility criteria of NMOS and PMOS, respectively. In addition, in FIG. 17, the case where the delay unit 31 is configured as a conventional inverter chain INV chain as in FIG. 4 and the case where it is implemented as a delay unit 40 of the present disclosure as shown in FIG. 7 are compared, and the black graph on the left represents the case where it is configured as an inverter chain INV chain, and the red graph on the right represents the case where it is implemented as a delay unit 40 of the present disclosure.

As shown in FIG. 17, it can be seen that the delay unit 40 of the present disclosure has less unnecessary margin at all process corners. However, when implemented with the SF (slow/fast) corner process, it has the least unnecessary margin. Therefore, the SRAM of the present disclosure may be manufactured with a process according to the SF (slow/fast) corner.

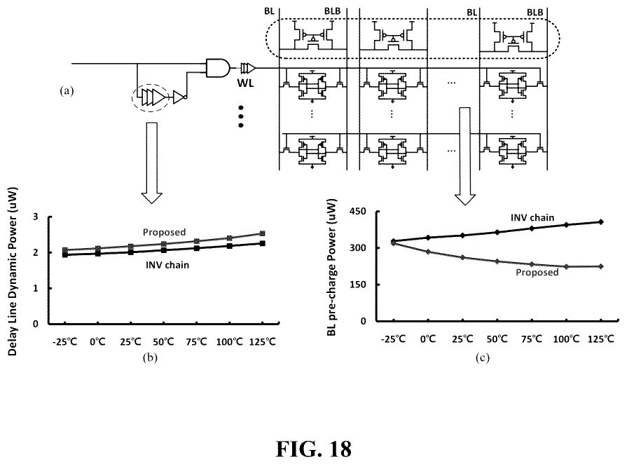

FIG. 18 is a graph comparing power consumption of a delay unit and bit line precharge depending on temperature.

In FIG. 18, (a) schematically illustrates a pulse signal generator 30 and a cell array 10 in an SRAM, (b) illustrates the power consumption of the pulse signal generator 30, and (c) illustrates the power consumption for precharging the BL within the cell array 10. In addition, in (b) and (c), the black graph illustrates the change in power consumption depending on temperature when the delay unit 31 is configured as an inverter chain INV chain, and the red graph illustrates the change in power consumption when implemented as the delay unit 40 of the present disclosure.

As shown in FIGS. 6 and 7, the delay unit 40 of the present disclosure has a variable delay unit 41 as well as an upper voltage generator 42 and a lower voltage generator 43, so that the power consumption is slightly greater than that of the case in which the delay unit 40 is configured only with an inverter chain INV chain. However, the cell array 10 has a plurality of bit line pairs BL/BLB, and even if one word line signal is activated, a voltage drop occurs in a plurality of bit line pairs BL/BLB. Therefore, if the unnecessary margin in the word line signal is reduced depending on temperature, the power for precharging a plurality of bit line pairs BL/BLB can be significantly reduced. As a result, the power consumption can be significantly reduced compared to the power consumption that increases due to the delay unit 40 of the present disclosure. In particular, the power consumption can be reduced even more significantly as the operating temperature of the SRAM increases.

In the illustrated embodiment, each component may have different functions and capabilities other than those described below, and may include additional components other than those described below. In addition, in an embodiment, each component may be implemented using one or more physically separated devices, implemented by one or more processors or a combination of one or more processors and software, and may not be clearly distinguished in specific operations, unlike the illustrated example.

Although the present disclosure has been described in detail through representative embodiments above, those skilled in the art will understand that many modifications and other equivalent embodiments can be derived from the embodiments described herein. Therefore, the true technical scope of the present disclosure is to be defined by the technical spirit set forth in the appended scope of claims.

What is claimed is:

1. A pulse signal generator comprising:
a delay unit that receives a clock signal, delays the clock signal, and outputs a delay clock signal while adjusting a delay time of the delay clock signal depending on temperature; and
a pulse generation circuit that receives the clock signal and the delay clock signal whose delay time is adjusted depending on temperature, and logically combines them to generate a pulse signal having a pulse width that varies depending on temperature.

2. The pulse signal generator according to claim 1,
wherein the delay unit includes:
an upper voltage generator that adjusts an upper voltage, which is a voltage of an upper node, depending on a voltage level of the clock signal and temperature;
a lower voltage generator that adjusts a lower voltage, which is a voltage of a lower node, depending on a voltage level of the clock signal and temperature; and
a variable delay unit that outputs the delay clock signal by delaying the received clock signal by different times, with an output driving ability adjusted for a level change of the clock signal depending on the upper voltage and the lower voltage.

3. The pulse signal generator according to claim 2,
wherein the variable delay unit includes:
a plurality of first variable inverters and a plurality of second variable inverters that are alternately connected in series to sequentially delay and transmit the received clock signal.

4. The pulse signal generator according to claim 3,
wherein a first variable inverter includes a first PMOS transistor and first and second NMOS transistors connected in series between a power supply voltage and a ground voltage,
the clock signal or an output of a previously arranged second variable inverter is applied to gates of the first PMOS transistor and the first NMOS transistor depending on an arrangement position of the first variable inverters, and
the lower voltage is applied to a gate of the second NMOS transistor.

5. The pulse signal generator according to claim 3,
wherein a second variable inverter includes second and third PMOS transistors and a third NMOS transistor, which are connected in series between a power supply voltage and a ground voltage,
an output of a first variable inverter previously arranged is applied to gates of the third PMOS transistor and the third NMOS transistor, and
the upper voltage is applied to a gate of the second PMOS transistor.

6. The pulse signal generator according to claim 2,
wherein the upper voltage generator lowers the upper voltage to different voltage levels depending on the temperature when an applied clock signal has a rising transition.

7. The pulse signal generator according to claim 2,
wherein the lower voltage generator increases the lower voltage to different voltage levels depending on the temperature when an applied clock signal has a rising transition.

8. The pulse signal generator according to claim 2,
wherein the upper voltage generator includes:
a first upper circuit that, in response to a rising transition of the clock signal, lowers the voltage of the upper node, but lowers it to a different voltage level depending on the temperature;
a second upper circuit that, in response to a rising transition of the clock signal, lowers the voltage level, but lowers it to a different voltage level depending on the temperature;
an upper buffer that buffers an applied clock signal and inputs it to the second upper circuit; and
an upper capacitor that is connected between the upper node and an output of the second upper circuit and transmits a change in the voltage level of the second upper circuit to the upper node by coupling.

9. The pulse signal generator according to claim 8,
wherein the first upper circuit includes:
a first upper PMOS transistor connected between a power supply voltage and the upper node, and having a gate to which the clock signal is applied;
a first upper diode transistor implemented as an NMOS transistor having one end and a gate connected to the upper node; and
a first upper NMOS transistor connected between the other end of the first upper diode transistor and a ground voltage, and having a gate to which the clock signal is applied.

10. The pulse signal generator according to claim 8,
wherein the second upper circuit includes:
a second upper PMOS transistor connected between a power supply voltage and the other end of the upper capacitor and having a gate to which the clock signal buffered in the upper buffer is applied;
a second upper diode transistor implemented as an NMOS transistor having one end and a gate connected to the other end of the upper capacitor; and
a second upper NMOS transistor connected between the other end of the second upper diode transistor and a ground voltage, and having a gate to which the clock signal buffered in the upper buffer is applied.

11. The pulse signal generator according to claim 2,
wherein the lower voltage generator includes:
a lower inverter that receives the clock signal, inverts it, and outputs an inverted clock signal;
a first lower circuit that increases the voltage of the lower node in response to a falling transition of the inverted clock signal, but increases it to a different voltage level depending on the temperature;
a second lower circuit that increases the voltage level in response to a falling transition of the inverted clock signal, but increases it to a different voltage level depending on the temperature;
a lower buffer that buffers the inverted clock signal and inputs it to the second lower circuit; and
a lower capacitor that is connected between the lower node and the output of the second lower circuit, and transmits a change in the voltage level of the second lower circuit to the lower node by coupling.

12. The pulse signal generator according to claim 11,
wherein the first lower circuit includes:
a first lower PMOS transistor having one end connected to a power supply voltage and having a gate to which the inverted clock signal is applied;
a first lower diode transistor implemented as an NMOS transistor having one end and a gate connected to the other end of the first lower PMOS transistor and the other end connected to the lower node; and
a first lower NMOS transistor connected between the lower node and a ground voltage and having a gate to which the inverted clock signal is applied.

13. The pulse signal generator according to claim 11,
wherein the second lower circuit includes:
a second lower PMOS transistor having one end connected to a power supply voltage and having a gate to which the inverted clock signal buffered in the lower buffer is applied;
a second lower diode transistor implemented as an NMOS transistor having one end and a gate connected to the other end of a first lower PMOS transistor and the other end connected to the other end of the lower capacitor; and
a second lower NMOS transistor connected between the other end of the lower capacitor and a ground voltage and having a gate to which the inverted clock signal buffered in the lower buffer is applied.

14. The pulse signal generator according to claim 1,
wherein the pulse generation circuit includes:
an inverter that inverts the delay clock signal and outputs an inverted delay clock signal; and
a logical AND circuit that logically ANDs the clock signal and the inverted delay clock signal to output the logical AND.

15. An SRAM comprising:
a cell array in which a plurality of bit cells is arranged, defined by a plurality of word lines and a plurality of bit line pairs; and
a word line driver having at least one pulse signal generator for outputting a word line signal having a pulse width that varies depending on temperature to the plurality of word lines.

16. The SRAM according to claim 15,
wherein the pulse signal generator comprises:
a delay unit that receives a clock signal, delays the clock signal, and outputs a delay clock signal while adjusting a delay time of the delay clock signal depending on temperature; and
a pulse generation circuit that receives the clock signal and the delay clock signal whose delay time is adjusted depending on temperature, and logically combines them to generate the word line signal having a pulse width that varies depending on temperature.

17. The SRAM according to claim 16,
wherein the delay unit includes:
an upper voltage generator that adjusts an upper voltage, which is a voltage of an upper node, depending on a voltage level of the clock signal and temperature;
a lower voltage generator that adjusts a lower voltage, which is a voltage of a lower node, depending on a voltage level of the clock signal and temperature; and
a variable delay unit that outputs the delay clock signal by delaying the received clock signal by different times, with an output driving ability adjusted for a level change of the clock signal depending on the upper voltage and the lower voltage.

18. The SRAM according to claim 17,
wherein the variable delay unit includes a plurality of first variable inverters and a plurality of second variable inverters that are alternately connected in series to sequentially delay and transmit the received clock signal,
a first variable inverter has a driving capability adjusted according to the lower voltage, and
a second variable inverter has a driving capability adjusted according to the upper voltage.

19. The SRAM according to claim 17,
wherein the upper voltage generator lowers the upper voltage to different voltage levels depending on the temperature when an applied clock signal has a rising transition.

20. The SRAM according to claim 17,
wherein the lower voltage generator increases the lower voltage to different voltage levels depending on the temperature when an applied clock signal has a rising transition.
